(19) United States
(12) Patent Application Publication
(10) Pub. No.: US 2013/0187236 A1
(43) Pub. Date: Jul. 25, 2013

(54) Methods of Forming Replacement Gate Structures for Semiconductor Devices

(71) Applicants: Ruilong Xie, Albany, NY (US); Xiuyu Cai, Albany, NY (US); Robert Miller, Yorktown Heights, NY (US); Andreas Knorr, Wappingers Falls, NY (US)

(72) Inventors: Ruilong Xie, Albany, NY (US); Xiuyu Cai, Albany, NY (US); Robert Miller, Yorktown Heights, NY (US); Andreas Knorr, Wappingers Falls, NY (US)

(73) Assignee: GLOBALFOUNDRIES INC., Grand Cayman (KY)

(21) Appl. No.: 13/354,844

(22) Filed: Jan. 20, 2012

(51) Int. Cl. H01L 27/092; H01L 21/28

(52) U.S. Cl. 257/369; 438/595; 257/E27.062; 257/E21.19

(57) ABSTRACT

Disclosed herein are methods of forming replacement gate structures. In one example, the method includes forming a sacrificial gate structure above a semiconducting substrate, removing the sacrificial gate structure to thereby define a gate cavity, forming a layer of insulating material in the gate cavity and forming a layer of metal within the gate cavity above the layer of insulating material. The method further includes forming a sacrificial material in the gate cavity so as to cover a portion of the layer of metal and thereby define an exposed portion of the layer of metal, performing an etching process on the exposed portion of the layer of metal to thereby remove the exposed portion of the layer of metal from within the gate cavity, and, after performing the etching process, removing the sacrificial material and forming a conductive material above the remaining portion of the layer of metal.

### BACKGROUND OF THE INVENTION

1. Field of the Invention

Generally, the present disclosure relates to the manufacturing of sophisticated semiconductor devices, and, more specifically, to various methods of forming replacement gate structures for various types of semiconductor devices.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein so-called metal oxide field effect transistors (MOSFETs or FETs) represent one important type of circuit element that substantially determines performance of the integrated circuits. A FET (whether an NFET or a PFET) is a device that typically includes a source region, a drain region, a channel region that is positioned between the source region and the drain region, and a gate electrode positioned above the channel region. Electrical contacts are made to the source and drain regions, and current flow through the FET is controlled by controlling the voltage applied to the gate electrode. If there is no voltage applied to the gate electrode, then there is no current flow through the device (ignoring undesirable leakage currents which are relatively small). However, when an appropriate voltage is applied to the gate electrode, the channel region becomes conductive, and electrical current is permitted to flow between the source region and the drain region through the conductive channel region. Traditionally, FETs have been substantially planar devices, but similar principles of operation apply to more three-dimensional FET structures, referred to herein as FinFETs.

To improve the operating speed of FETs, and to increase the density of FETs within an integrated circuit module, device designers have greatly reduced the physical size of FETs over the years. The channel length of FETs has been significantly decreased, in order to improve the switching speed of FETs, but that has made controlling the detrimental leakage current more difficult.

For many device technology generations, the gate electrode structures of most transistor elements (FETs and FinFETs) have comprised a plurality of silicon-based materials, such as a silicon dioxide and/or silicon oxynitride gate insulation layer, in combination with a polysilicon gate electrode. However, to accommodate the channel length of aggressively scaled transistor elements, new materials and structures were developed and many newer generation devices employ gate electrode stacks comprising alternative materials and structures in an attempt to provide better leakage control and to increase the amount of current that can be delivered for an applied gate electrode voltage. For example, in some aggressively scaled transistor elements, which may have channel lengths that are less than about 45 nm, gate electrode stacks comprising a so-called high-k dielectric/metal gate (HK/MG) configuration have been shown to provide significantly enhanced operational characteristics over the heretofore more commonly used silicon dioxide/polysilicon (SiO/poly) configurations. The insulating component of these HK/MG gate electrode stacks may employ oxides of aluminum (Al), hafnium (Hf), titanium (Ti), sometimes combined with additional elements such as carbon, (C), silicon (Si), or nitrogen (N), and the conductive electrode component may again employ these materials (not as oxides), alone or in productive combinations to achieve desired properties.

One well-known processing method that has been used for forming a transistor with a high-k/metal gate structure is the so-called “gate last” or “replacement gate” technique. FIGS. 1A-1D depict one illustrative prior art method for forming an HK/MG replacement gate structure on an illustrative FET transistor 100 using a gate-last technique. As shown in FIG. 1A, the process includes the formation of a basic transistor structure 100 above a semiconducting substrate 10 in an active area defined by a shallow trench isolation structure 11. At the point of fabrication depicted in FIG. 1A, the device 100 includes a sacrificial or dummy gate insulation layer 12, a dummy or sacrificial gate electrode 14, sidewall spacers 16, a layer of insulating material 17 and source/drain regions 18 formed in the substrate 10. The various components and structures of the device 100 may be formed using a variety of different materials and by performing a variety of known techniques. For example, the sacrificial gate insulation layer 12 may be comprised of silicon dioxide, the sacrificial gate electrode 14 may be comprised of polysilicon, the sidewall spacers 16 may be comprised of silicon nitride and the layer of insulating material 17 may be comprised of silicon dioxide. The source/drain regions 18 may be comprised of implanted dopant materials (N-type dopants for NFET devices and P-type dopants for PFET devices) that are implanted into the substrate 10 using known masking and ion implantation techniques. Of course, those skilled in the art will recognize that there are other features of the transistor 100 that are not depicted in the drawings for purposes of clarity. For example, so-called halo implant regions are not depicted in the drawings, as well as various layers or regions of silicon germanium that may be employed in high-performance PFET transistors. At the point of fabrication depicted in FIG. 1A, the various structures of the device 100 have been formed and a chemical mechanical polishing process (CMP) has been performed to remove any materials above the sacrificial gate electrode 14 (such as a protective cap layer (not shown) comprised of silicon nitride) so that the sacrificial gate electrode 14 may be removed.

As shown in FIG. 1B, one or more etching processes are performed to remove the sacrificial gate electrode 14 and the sacrificial gate insulation layer 12 without damage to the sidewall spacers 16 and the insulating material 17 to thereby define a gate opening 20 where a replacement gate structure will be subsequently formed. Any masking layers used to confine the etching to selected regions would also have been removed at this point of the process sequence. Typically, the sacrificial gate insulation layer 12 is removed as part of the replacement gate technique, as depicted herein. However, the sacrificial gate insulation layer 12 may not be removed in all applications.

Next, as shown in FIG. 1C, various layers of material that will constitute a replacement gate structure 30 are formed in the gate opening 20. However, although not depicted in the drawings, the generally squared-edge gate opening may cause certain problems in forming such layers of material in the gate opening 20. For example, such a squared-edge gate opening 20 may lead to the formation of voids in one or more of the layers of material that will be formed in the gate opening 20. In one illustrative example, the replacement gate structure 30 is comprised of a high-k gate insulation layer 30A having a thickness of approximately 2 nm, a work-function adjusting layer 30B comprised of a metal (e.g., a layer of titanium nitride) with a thickness of 2-5 nm and a bulk metal layer 30C (e.g., aluminum). Ultimately, as shown in FIG. 1D, a CMP process is performed to remove excess portions of the gate insulation layer 30A, the work-function adjusting layer 30B and the bulk metal layer 30C positioned outside of the gate opening 20 to define the replacement gate structure 30. The materials used for the replacement gate structures 30 for NFET devices and PFET devices, as well as N-FinFET and P-FinFET devices may be different.

As device dimensions have been constantly reduced, and packing densities have been increased in recent years, the formation of conductive contacts that are electrically coupled to underlying devices, such as the illustrative transistor 100, have become more problematic. In some cases, the conductive contacts have become so small, due to the limited plot space available to form the conductive contacts, that it is difficult to directly define the conductive contact using traditional photolithographic and etching tools and techniques. In some applications, device designers now employ so-called self-aligned contacts in an effort to overcome some of the problems associated with trying to directly pattern such conductive contacts. However, in using self-aligned contacts, it is important that the process flow selected be as compatible with existing processes as possible, while minimizing the complexity of existing process flows used in manufacturing production devices.

The present disclosure is directed to various, more efficient methods of forming replacement gate structures for various types of semiconductor devices that may at least reduce or eliminate one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming replacement gate structures for various types of semiconductor devices. The novel devices and methods disclosed herein may be applied in a variety of situations with a variety of different devices, such as, for example, highly scaled devices where the gate electrode is in close proximity to the conductive contacts made to the source and drain regions of a transistor device. In one example, the method includes forming a sacrificial gate structure above a semiconducting substrate, removing the sacrificial gate structure to thereby define a gate cavity, forming a layer of insulating material in the gate cavity and forming a layer of metal within the gate cavity above the layer of insulating material. In this embodiment, the method further includes forming a sacrificial material in the gate cavity so as to cover a portion of the layer of metal and thereby define an exposed portion of the layer of metal, performing an etching process on the exposed portion of the layer of metal to thereby remove the exposed portion of the layer of metal from within said gate cavity, and, after performing the etching process, removing the sacrificial material and forming a conductive material above the previously covered portion of the layer of metal.

Another illustrative method disclosed herein includes the steps of forming a sacrificial gate structure above a semiconducting substrate, removing the sacrificial gate structure to thereby define a gate cavity, forming a layer of insulating material in the gate cavity and forming a first layer of metal within the gate cavity above the layer of insulating material. In this embodiment, the method further comprises forming a second layer of metal within the gate cavity above the first layer of metal, forming a sacrificial material in the gate cavity so as to cover a portion of the second layer of metal and thereby define an exposed portion of the first layer of metal and the second layer of metal, performing at least one etching process on the exposed portions of the second layer of metal and the first layer of metal to thereby remove the exposed portions of the second layer of metal and the first layer of metal from within the gate cavity, and, after performing the at least one etching process, removing the sacrificial material and forming a conductive gate electrode material above the previously covered portions of the first and second layers of metal.

One illustrative embodiment of a device disclosed herein includes a first transistor and a second transistor formed in and above a semiconducting substrate, wherein each of the first and second transistors comprises a gate insulation layer, a first work function adjusting metal layer positioned above the gate insulation layer and a gate electrode positioned above the first work function adjusting metal layer. In this embodiment, the gate electrode for each of the first and second transistors has an upper portion with a width at its top that is greater than a width of a lower portion of the gate electrode at its bottom. The device further includes a second work function adjusting layer positioned between the first work function adjusting layer and the gate electrode only in the second transistor. The upper portion of the gate electrode of the first transistor is positioned above and contacts an upper surface of the first work function adjusting layer and also contacts the gate insulation layer. The upper portion of the gate electrode of the second transistor is positioned above and contacts an upper surface of each of the first and second work function adjusting layers and also contacts the gate insulation layer. In one illustrative embodiment, the first transistor may be an NFET device while the second transistor may be a PFET device. In other illustrative embodiments, the first transistor may be a PFET device while the second transistor may be an NFET device.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1D depict one illustrative prior art process flow for forming a semiconductor device using a gate last approach;

FIGS. 2A-2Q depict one illustrative method disclosed herein for forming replacement gate structures for a semiconductor device; and

FIGS. 3A-3E depict another illustrative method disclosed herein for forming replacement gate structures for a semiconductor device.

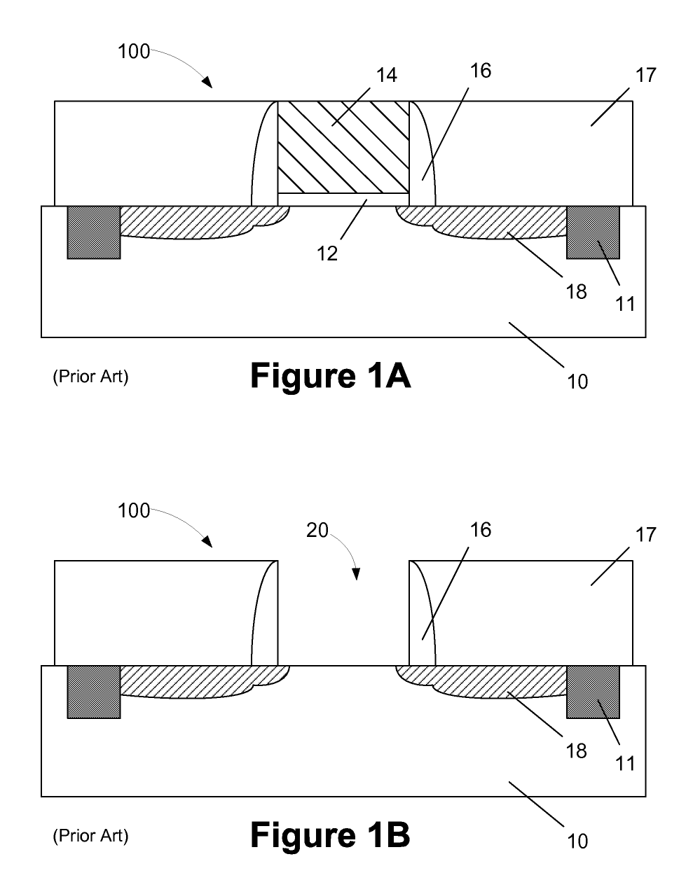

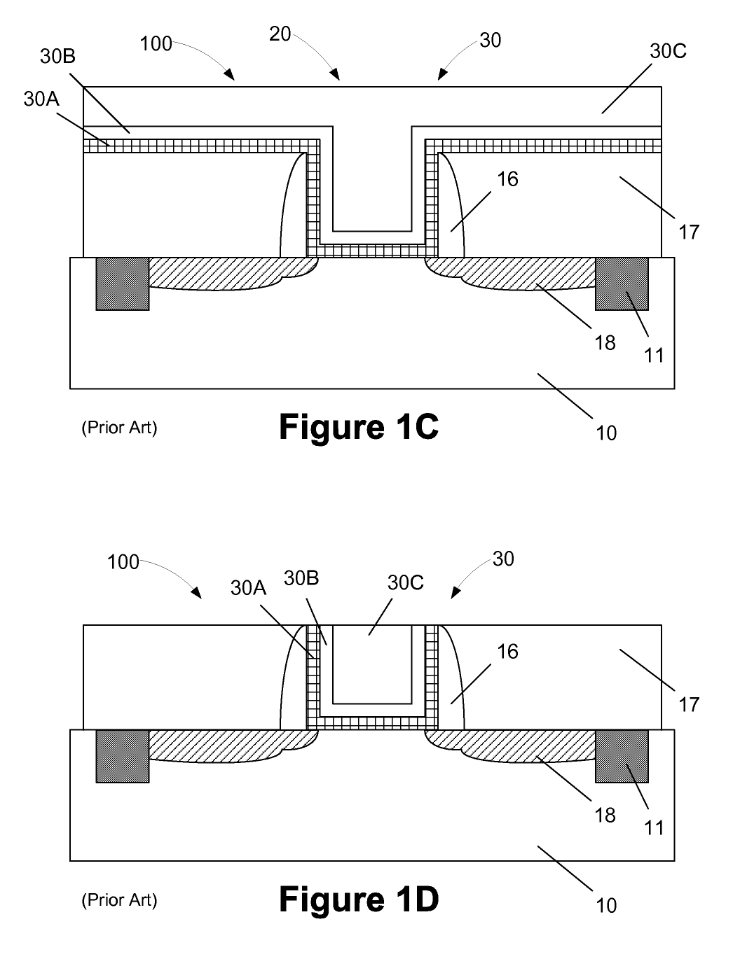

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of forming replacement gate structures for various types of semiconductor devices, such as FinFETs and planar field effect transistors. As will be readily apparent to those skilled in the art upon a complete reading of the present application, the methods and structures disclosed herein may be applicable to a variety of devices, e.g., NFET, PFET, CMOS, etc., and they are readily applicable to a variety of integrated circuits, including, but not limited to, ASICs, logic devices and circuits, memory devices and systems, etc. With reference to the attached drawings, various illustrative embodiments of the methods and devices disclosed herein will now be described in more detail.

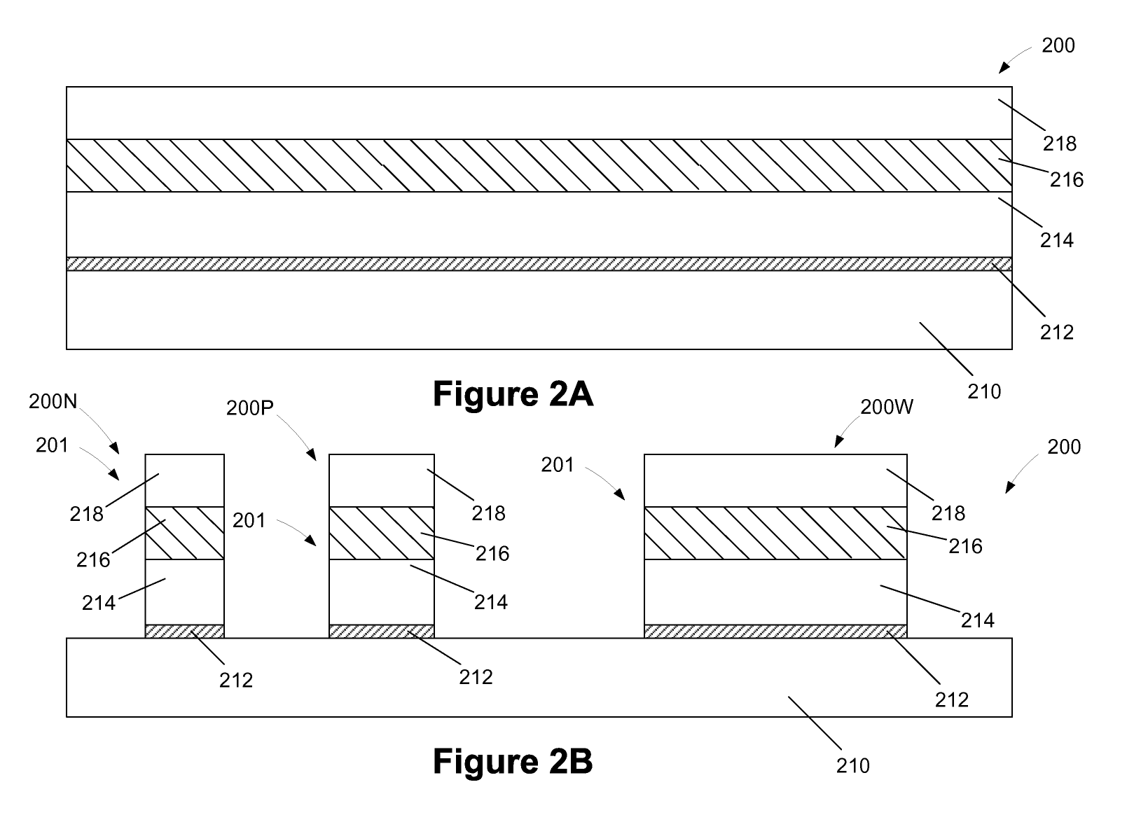

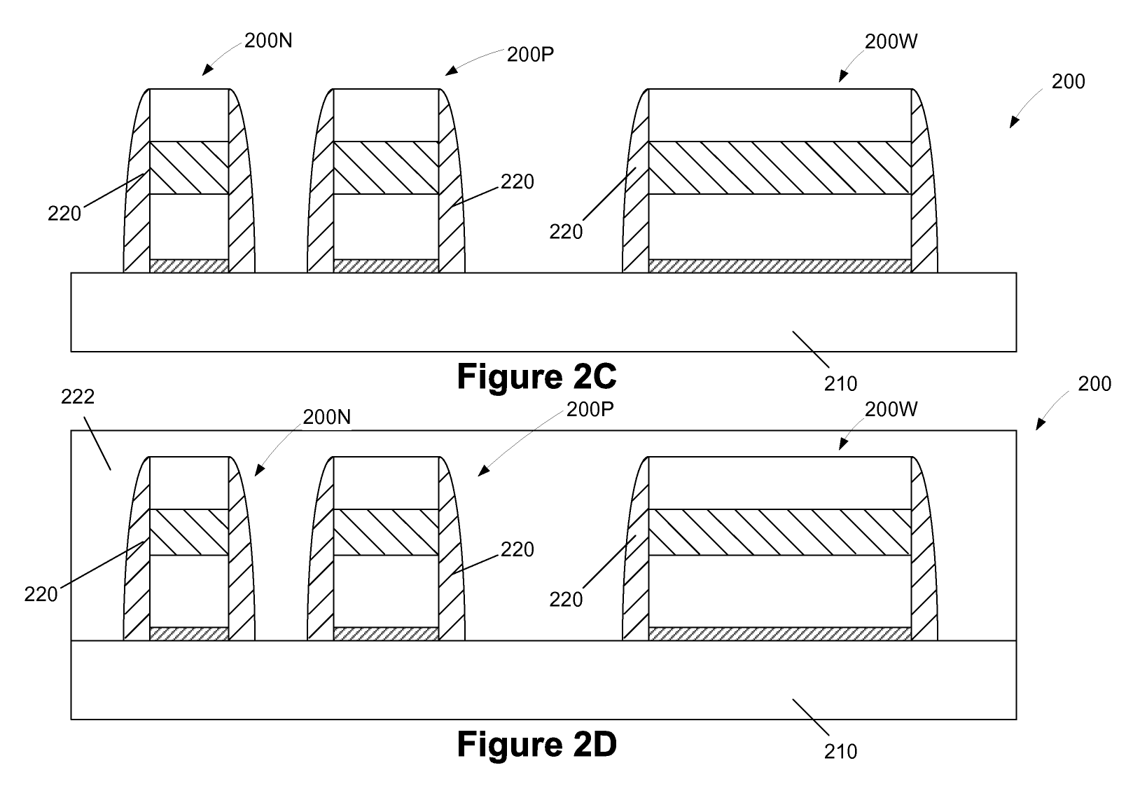

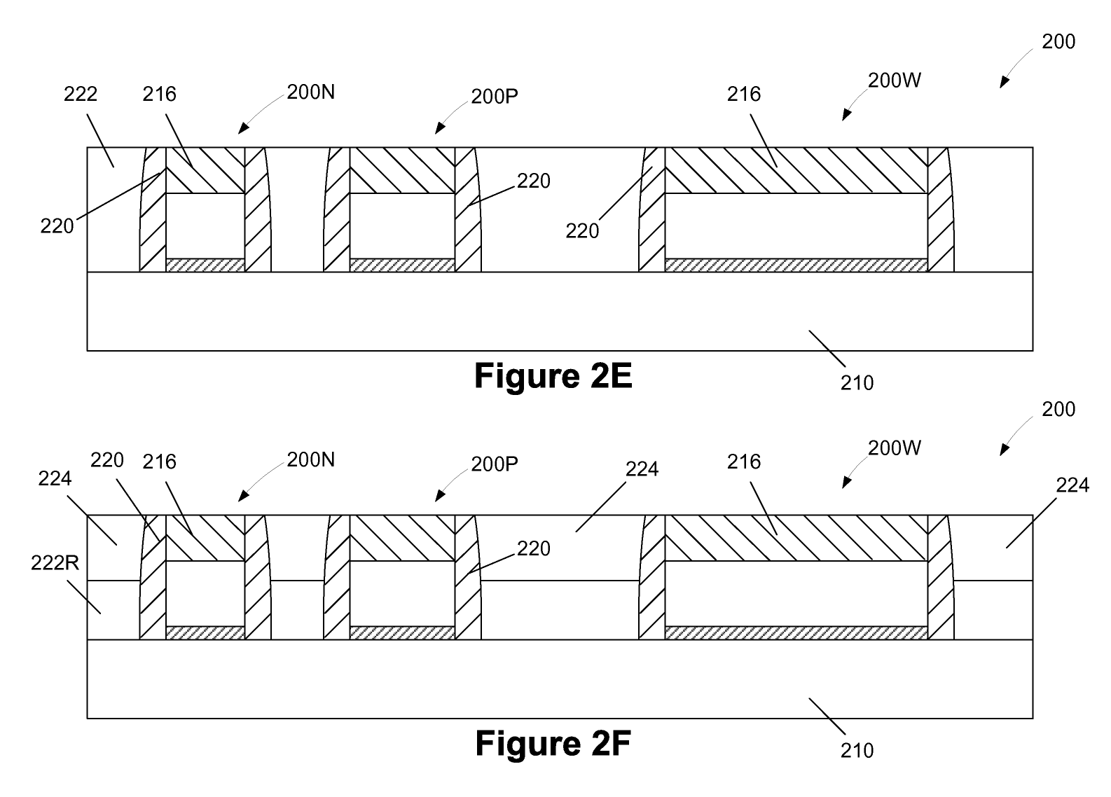

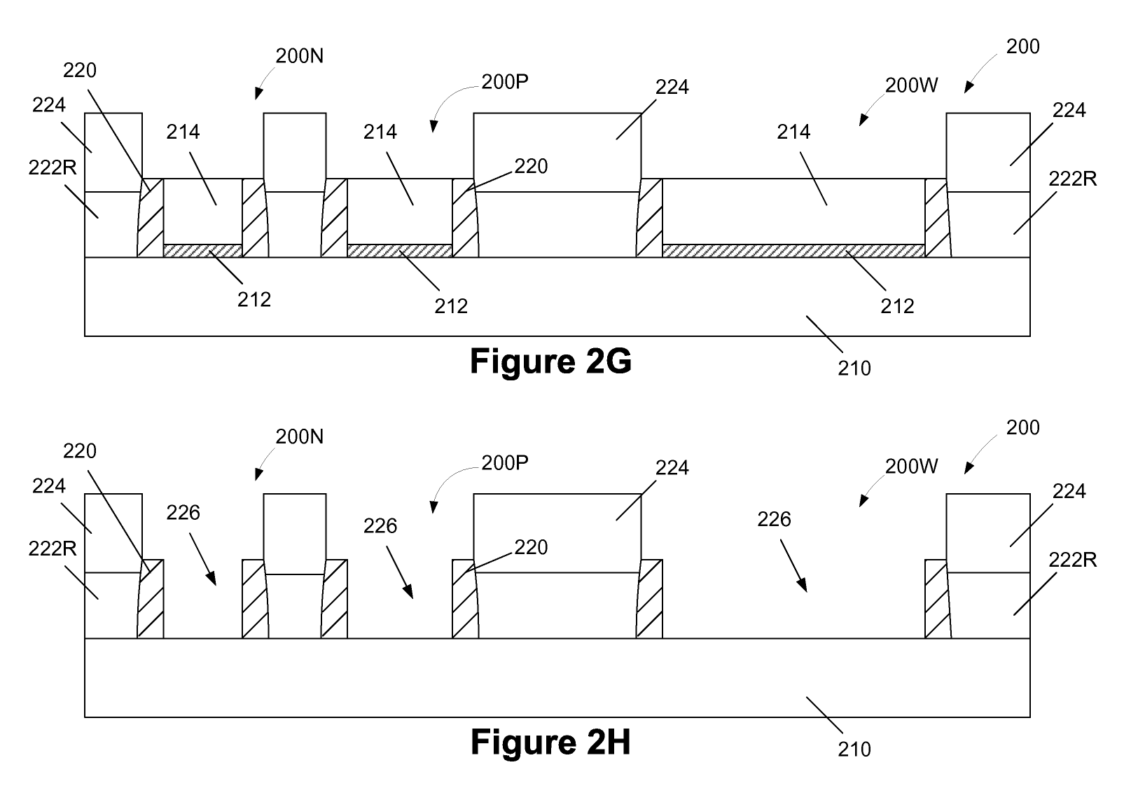

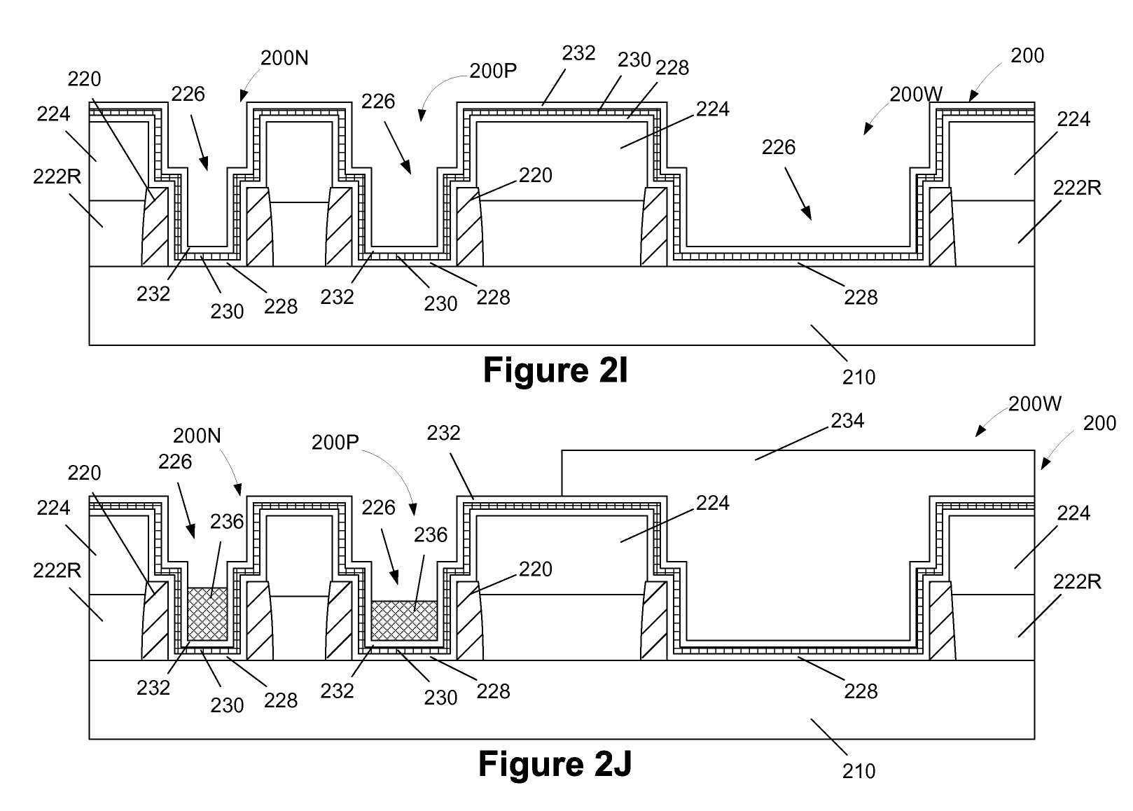

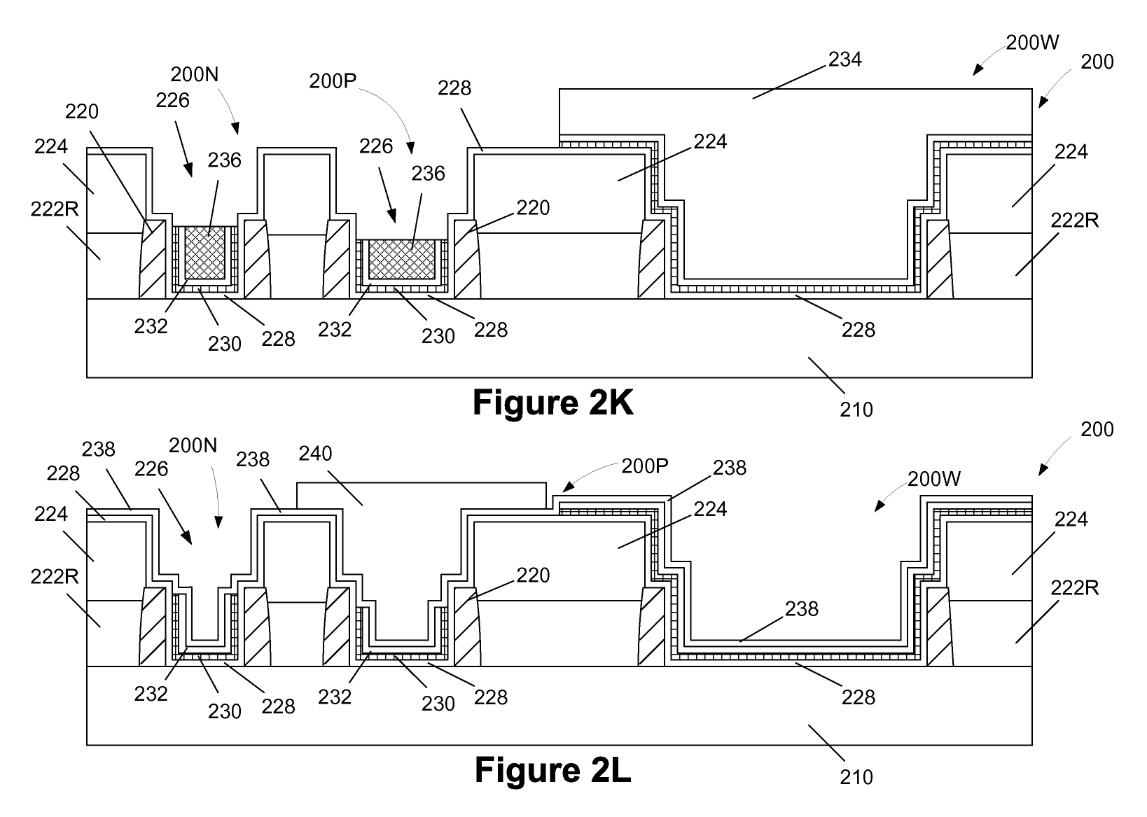

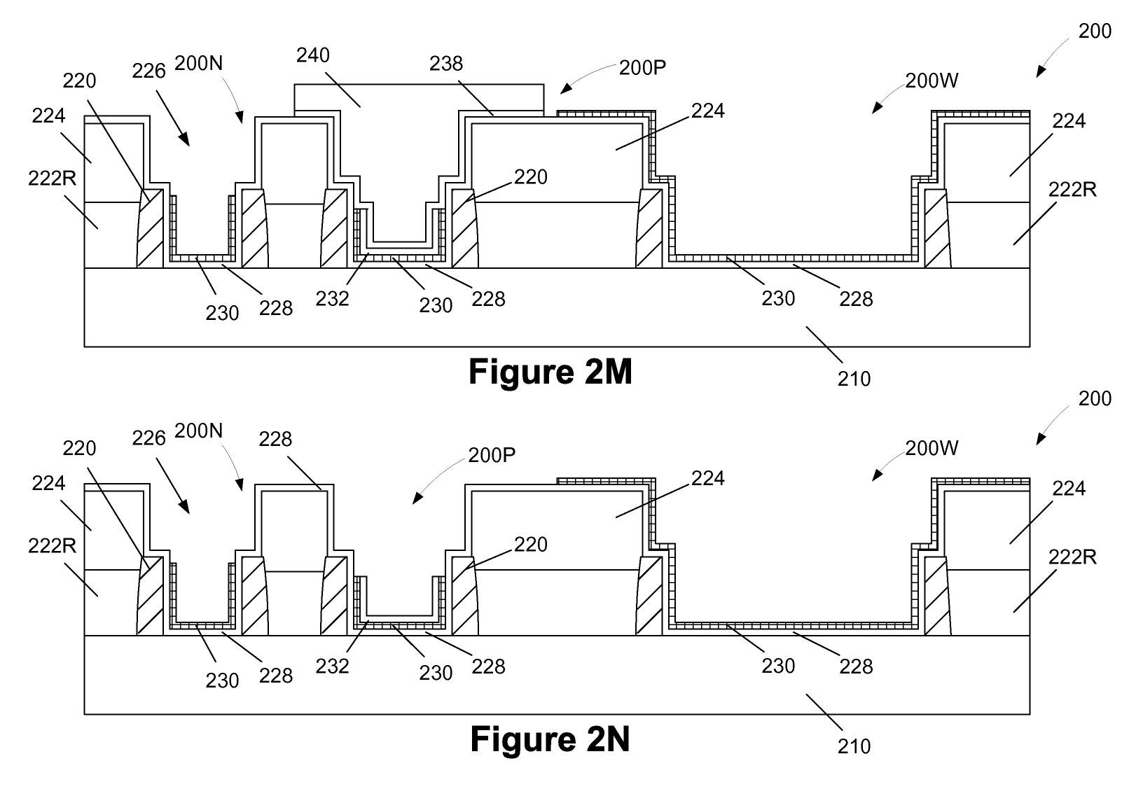

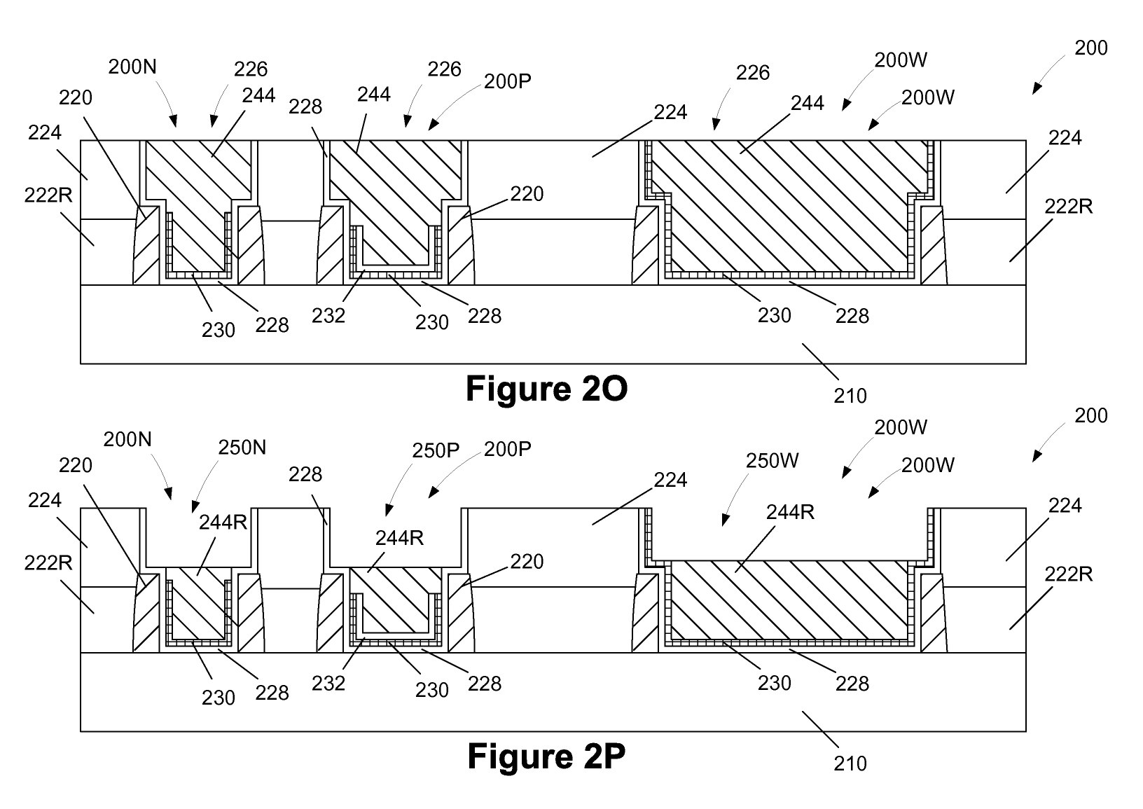

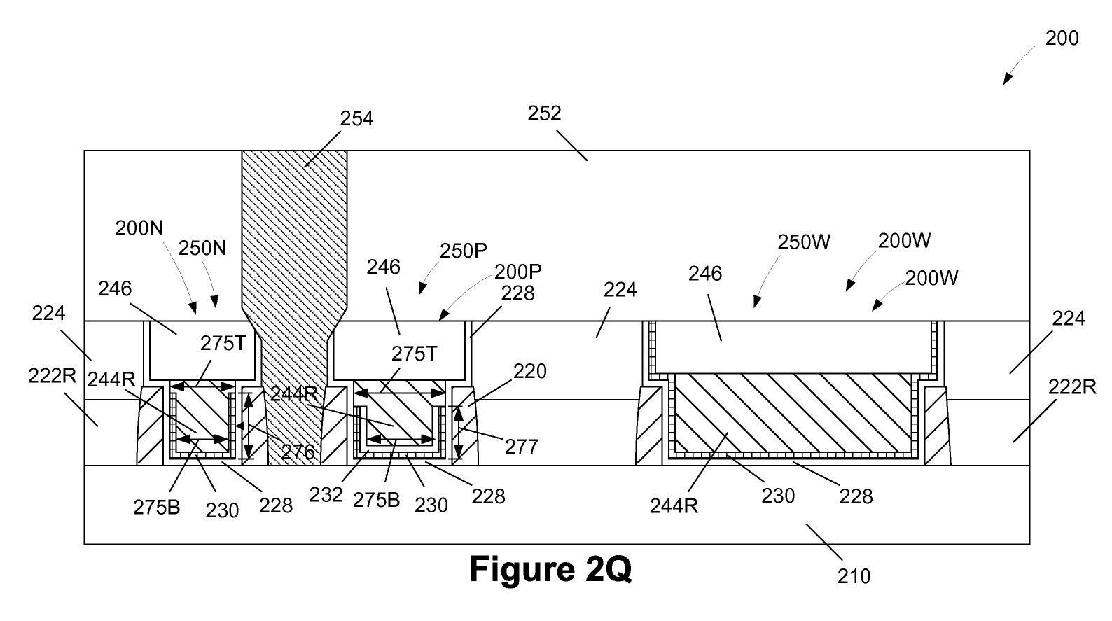

FIG. 2A is a simplified view of an illustrative transistor 200 at an early stage of manufacturing that is formed above a semiconducting substrate 210. The inventions disclosed herein may be employed on either FinFETs or planar FETs, either of which may be either an N-type or a P-type device. For purposes of disclosure, the present inventions will be disclosed in the context of forming an illustrative planar transistor, however, the inventions disclosed herein should not be considered as limited to such an illustrative embodiment. For ease of illustration and so as to not obscure the present inventions, various doped regions that are formed in the substrate 210, such as halo implant regions, source/drain regions, etc., are not depicted. Such doped regions may be formed by using known ion implantation tools and techniques which are well known to those skilled in the art. The substrate 210 may have a variety of configurations, such as the depicted bulk silicon configuration. The substrate 210 may also have a silicon-on-insulator (SOI) configuration that includes a bulk silicon layer, a buried insulation layer and an active layer, wherein semiconductor devices are formed in and above the active layer. Thus, the terms substrate or semiconductor substrate should be understood to cover all forms of semiconductor structures. The substrate 210 may also be made of materials other than silicon.

At the point of fabrication depicted in FIG. 2A, several layers of material have been formed above the substrate 210. In the depicted example, a sacrificial gate insulation layer 212, a sacrificial gate electrode layer 214, a first hard mask layer 216 and a second hard mask layer 218 may be formed above the substrate 210 using a variety of known techniques. In one illustrative embodiment, the sacrificial gate insulation layer 212 may be comprised of silicon dioxide, the sacrificial gate electrode layer 214 may be comprised of polysilicon, the first hard mask layer 216 may be comprised of silicon nitride and the second hard mask layer 218 may be comprised of silicon dioxide. The thickness of these various layers may vary depending upon the particular application. The sacrificial material layers shown in FIG. 2A may be formed by performing a variety of known processes, e.g., a thermal growth process, a chemical vapor deposition (CVD) process, an atomic layer deposition (ALD) process, or plasma-enhanced versions of such processes.

Next, as shown in FIG. 2B, one or more etching processes are performed to define a plurality of material stacks 201 for use in forming an illustrative NFET device 200N, an illustrative PFET device 200P and an illustrative wide gate length device 200W (which could equally as well be an NFET or a PFET device). The devices 200N, 200P and 200W may be formed in and above separately defined active regions that are defined by isolation structures (not shown) formed in the semiconducting substrate 210. In general, the gate lengths of the devices 200N, 200P and 200W may vary depending upon the particular application. In one illustrative embodiment, the devices 200N, 200P may have gate lengths on the order of 40 nm or less, and the completed devices 200N, 200P may be employed in applications requiring high switching speed, e.g., microprocessors, memory devices. The gate lengths of the NFET device 200N and the PFET device 200P need not be the same. The wide gate length devices 200W may typically have a relatively large gate length, e.g., 150+ nm, and such devices 200W may be employed in applications like high-power applications, Input/Output circuits, etc. Although the devices 200N, 200P and 200W are depicted as being formed adjacent one another, in practice, the devices 200N, 200P and 200W may be spread out across the substrate 210.

Next, as shown in FIG. 2C, sidewall spacers 220 are formed proximate the material stacks 201 for the devices 200N, 200P, 200W. The spacers 220 may be formed by depositing a layer of spacer material, e.g., silicon nitride, and thereafter performing an anisotropic etching process. Various cleaning processes may be performed at this point in the process as well. FIG. 2D depicts the device 200 after a layer of insulating material 222 is formed above the device 200. In one illustrative embodiment, the layer of insulating material 222 may be a flowable silicon dioxide (doped or undoped), a so-called HARP silicon dioxide, etc. The layer of insulating material 222 may be formed by performing a variety of well-known processes, and, at this step in the process flow, the top surface of the insulating material layer 222 need not be a flat surface.

As depicted in FIG. 2E, a chemical mechanical polishing (CMP) process is then performed on the layer of insulating material 222 with the first hard mask layer 216, e.g., silicon nitride, acting as a polish-stop. Then, as shown in FIG. 2F, an etching process is performed to reduce the thickness of the layer of insulating material 222 and thereby define a reduced thickness layer of insulating material 222R. Thereafter, a second layer of insulating material 224 is formed above the reduced thickness layer of insulating material 222R. A CMP process is then performed on the second layer of insulating material 224 again using the first hard mask layer 216 as a polish-stop. The second layer of insulating material 224 may be comprised of a variety of materials, e.g., a HDP oxide, a HARP oxide, carbon-doped silicon dioxide, a PECVD oxide, etc., that may be initially formed using a variety of known techniques.

Next, as shown in FIG. 2G, one or more etching processes are performed to remove the first hard mask layer 216 and expose the sacrificial gate electrode layer 214 for further processing. In the illustrative embodiment where the first hard mask layer 216 and the sidewall spacers 220 are made of the same material, this etching process also reduces the height of the spacers 220. Then, as shown in FIG. 2H, one or more etching processes are performed to remove the sacrificial gate electrode layer 214 and the sacrificial gate insulation layer 212. In the depicted embodiment, the etching process results in the definition of a gate cavity 226 for each of the devices 200N, 200P and 200W.

Next, as shown in FIG. 2I, various layers of material that will constitute a replacement gate structure 250 (discussed below) are initially formed in the gate openings 226. The replacement gate structure 250 may be formed using a variety of known techniques such as those described in the background section of this application. In one illustrative example, this involves the conformable deposition of a high-k gate insulation layer 228 having a thickness of approximately 2 nm, a first work function adjusting layer 230 for the NFET device 200N comprised of a metal (e.g., a layer of titanium nitride) with a thickness of 2-5 nm and optionally a second work function adjusting layer 232 for the PFET device 200P comprised of a metal (e.g., lanthanum, aluminum, magnesium, etc.) with a thickness of about 1-5 nm. As will be recognized by those skilled in the art after a complete reading of the present application, the order in which the layers 230, 232 are formed may be reversed depending on the particular application.

The high-k gate insulation layer 228 may be comprised of a variety of high-k materials (k value greater than 10), such as hafnium oxide, hafnium silicate, lanthanum oxide, zirconium oxide, etc. The metal layers 230, 232 may be comprised of a variety of metal gate electrode materials which may include, for example, one or more layers of titanium (Ti), titanium nitride (TiN), titanium-aluminum (TiAl), aluminum (Al), aluminum nitride (AlN), tantalum (Ta), tantalum nitride (TaN), tantalum carbide (TaC), tantalum carbonitride (TaCN), tantalum silicon nitride (TaSiN), tantalum silicide (TaSi) and the like. Additionally, the composition of the replacement gate structure 250 for the various devices 200N, 200P and 200W may be different. Thus, the particular details of construction of replacement gate structures 250, and the manner in which such replacement gate structures 250 are formed, should not be considered a limitation of the present invention unless such limitations are expressly recited in the attached claims. The methods disclosed herein may also be employed in replacement gate structures 250 that do not employ a high-k gate insulation layer, although a high-k gate insulation layer will likely be used in most applications.

Next, as shown in FIG. 2J, a masking layer 234, a soft or hard mask, is formed above the device 200W and exposes the devices 200N, 200P for further processing. In one illustrative embodiment, the masking layer 234 is a patterned layer of photoresist material. The masking layer 234 may be formed using traditional tools and methods.

Then, as is also shown in FIG. 2J, one or more process operations are performed to form a sacrificial material layer 236 in the lower portions of the gate cavities 226. As described more fully below, the sacrificial material layer 236 acts to cover portions of both of the first work function adjusting layer 230 and the second work function adjusting layer 232, thereby defining exposed portions of the metal layers 230 and 232 for further processing. The sacrificial material layer 236 layer may be comprised of a variety of materials and it may be formed using a variety of techniques which provide the process characteristics of substantially bottom-up gap fill, such as a flowable oxide, or some recently developed processes with chemical precursors specifically selected to promote substantial bottom-up growth within gaps or trenches. For example, the systems and processes described in U.S. Pat. Nos. 7,888,233 and 7,915,139 that are assigned to Novellus Systems, Inc. may be useful in manufacturing the sacrificial material 236. Of course, other systems and processes may be employed to form the sacrificial material 236, such as those described in US Patent Publication No 2011/0014798 that is assigned to Applied Materials. U.S. Pat. Nos. 7,888,233 and 7,915,139 and US Patent Publication No. 2011/0014798 are each hereby incorporated by reference in their entirety.

In general, the aforementioned Novellus patents describe a process whereby the process gas contains a silicon-containing compound and an oxidant. Suitable silicon-containing compounds include organo-silanes and organo-siloxanes. In certain embodiments, the silicon-containing compound is a commonly available liquid phase silicon source. In some embodiments, a silicon-containing compound having one or more mono, di, or tri-ethoxy, methoxy or butoxy functional groups may be used. Examples include, but are not limited to, TOMCAT, OMCAT, TEOS, tri-ethoxy silane (TES), TMS, MTEOS, TMOS, MTMOS, DMDMOS Diethoxy silane (DES), triphenylethoxysilane, 1-(triethoxysilyl) 2-(diethoxymethylsilyl)ethane, tri-t-butoxylsilanol and tetramethoxy silane. Examples of suitable oxidants include ozone, hydrogen peroxide and water. In some embodiments, the silicon-containing compound and the oxidant are delivered to a reaction chamber via a liquid injection system that vaporizes the liquid for introduction to the chamber. The reactants are typically delivered separately to the chamber. Typical flow rates of the liquid introduced into the liquid injection system range from 0.1-5.0 mL/min per reactant. Of course, one of skill in the art having benefit of the present disclosure will understand that optimal flow rates depend on the particular reactants, desired deposition rate, reaction rate and other process conditions. As discussed above, the reaction typically takes place in dark or non-plasma conditions. Chamber pressure may be between about 1-100 Torr, in certain embodiments, it is between 5 and 20 Torr, or 10 and 20 Torr. In a particular embodiment, chamber pressure is about 10 Torr. During the process, the substrate temperature is typically between about −20-100° C. In certain embodiments, the temperature is between about 0-35° C. The pressure and the temperature may be varied to adjust the deposition time. In one example, high pressure and low temperature are generally favorable for quicker deposition time. Conversely, a high temperature and low pressure will result in slower deposition time. Thus, increasing temperature may require increased pressure. In one embodiment, the temperature is about 5° C. and the pressure about 10 Torr.

In one illustrative embodiment, the sacrificial material layer 236 is a layer of flowable oxide that is formed by performing a substantially bottom-up gap fill process that may be subsequently easily removed using a dilute HF wet process. In the example depicted herein, the PFET device 200P has a larger gate length than the NFET device 200N. Using a bottom-up CVD dielectric process to form a material such as a flowable oxide, the sacrificial material layer 236 tends to form more rapidly in smaller cavities than in larger cavities. Thus, the sacrificial material layer 236 in the NFET device 200N may be manufactured so as to have a greater thickness than the sacrificial material layer 236 in the PFET device 200P. The extent to which the sacrificial material layer 236 fills the gate cavities 226 for the NFET device 200N and the PFET device 200P may be controlled by controlling the deposition time and the chemical parameters of the process used to form the sacrificial material layer 236. In one illustrative embodiment, the thickness of the sacrificial material layer 236 may be 20-50 nm. Additionally, if desired, the illustrative order of forming the masking 234 and the sacrificial layer 236 may be reversed.

Then, as shown in FIG. 2K, using the sacrificial material layer 236 as a mask for the 200N and 200P devices and the layer 234 as a mask for the 200W device, one or more etching processes are performed to remove the exposed portions of the first work function adjusting layer 230 and the second work function adjusting layer 232 (i.e., the portions of the layers 230, 232 above the upper surface of the sacrificial material layer 236) from within the gate cavities 226 of both the NFET device 200N and the PFET device 200P. At this point in the fabrication process, after the etching process(es) is performed, the remaining portions of the layers 230, 232 are still protected by the sacrificial material layer 236 on devices 200N and 200P and by the masking layer 234 on device 200W. In the depicted embodiment, the etch rate and time of the etching process performed on the exposed portions of the layers 230, 232 are adjusted such that the remaining portions of the first work function adjusting layer 230 and the second work function adjusting layer 232 are at a level that is approximately even with the upper surface of the sacrificial material layer 236 in each of the NFET device 200N and the PFET device 200P. In the illustrative embodiment depicted herein, the high-k insulation layer 228 is resistant to the etchant and is thus not removed from the gate cavity 226 of either the NFET device 200N or the PFET device 200P. However, in some applications, depending upon the etchant used, portions of the high-k insulating material 228 positioned above the upper surface of the sacrificial material layer 236 may be removed.

FIG. 2L depicts the device 200 after several process operations have been performed. The sacrificial material layer 236 has been removed from the gate cavities 226 for the NFET device 200N and the PFET device 200P, and the masking layer 234 has been removed from above the device 200W. This exposes the remaining portions of the metal layer 230, 232 for further processing. Then, a relatively thin hard mask 238, e.g., silicon dioxide, is conformably deposited above the device 200 and in the gate cavities 226 for the devices 200N, 200P and 200W. Thereafter, another patterned masking layer 240, a soft or a hard mask, is formed above the device 200 so as to cover the PFET device 200P and expose the NFET device 200N and optionally the wide device 200W for further processing. In one illustrative embodiment, the masking layer 240 is a patterned layer of photoresist material. The masking layer 240 may be formed using traditional tools and methods.

FIG. 2M depicts the device 200 after several process operations have been performed. First, an etching process is performed to remove the exposed portions of the hard mask layer 238 in the NFET device 200N and optionally the wide device 200W, i.e., to remove the portions of the hard mask layer 238 that are not covered by the patterned mask layer 240. Then, a second etching process is performed to remove the remaining portion of the second work function adjusting layer 232 (that was previously covered by the sacrificial material layer 236) from within the cavities 226 of the NFET device 200N and optionally the wide device 200W. Thus, in the illustrative example depicted herein, only the protected segment of the first work function adjusting layer 230 and the high-k layer of insulating material 228 remain in the gate cavities 226 for the NFET device 200N and the wide device 200W. The high-k layer of insulating material 228 and the remaining portions of the first work function adjusting layer 230 and the second work function adjusting layer 232 are positioned in the gate cavity 226 for the PFET device 200P. Of course, as mentioned earlier, in some embodiments, using different combinations of work function adjusting materials, the NFET device 200N could be masked instead of the PFET device 200P. FIG. 2N depicts the device 200 after the patterned masking layer 240 has been removed from the PFET device 200P.

Next, as shown in FIG. 20, a conductive structure 244, e.g., a metal, is formed in each of the gate cavities 226. In some applications, the conductive structure 244 may be different for the various devices 200N, 200P and/or 200W. In one illustrative example, the conductive structure 244 may be comprised of aluminum, tungsten, etc. The conductive structure 244 may be formed by initially depositing a layer of conductive material so as to over-fill the gate cavities 226 and thereafter performing a CMP process to remove excess portions of the layer of conductive material positioned outside of the gate cavities 226. This CMP process also provides for the removal of excess metal layer 232 outside the gate cavity 226 above the 200W device.

Next, as shown in FIG. 2P, an etching process is performed to reduce the original thickness of the conductive structure 244 and thereby define a reduced thickness conductive structure 244R that will ultimately become part of the final gate electrode structures 250N, 250P and 250W. By virtue of removing portions of the first work function adjusting layer 230 and the second work function adjusting layer 232 from within the upper portions of the cavities 226 of the NFET device 200N and the PFET device 200P, the recessing of the conductive structure 244 is a relatively simpler process. That is, the etching process performed to reduce the original thickness of the conductive structure 244 involves etching only a single metal. This eliminates the need to achieve balanced etching rates of several dissimilar materials, where, alternatively, leaving the layers 230 and 232 at full height unetched would have resulted in a higher risk of undesired electrical shorting to nearby contacts to source and drain regions. The presence of the first work function adjusting layer 230 and the second work function adjusting layer 232 in the upper portion of the cavity 226 of the wide device 200W is not as problematic because there is less negative design scaling impact to allowing larger gate-to-contact spacing in that application, thus obviating the imperative for self-aligned contacts on those devices.

Next, as shown in FIG. 2Q, a layer of insulating material 246 is deposited and polished, which serves as a dielectric cap layer on top of the gate metals that prevents the source/drain contact shorting to the gate. Then, another layer of insulating material 252 is formed above the device 200 and an illustrative self-aligned contact 254 is formed using conventional techniques. The insulating material 246 needs to be a material that is more etch-resistant than insulating materials 224 and 222R in order to effectively guide the self-alignment of the contact etch. The contact 254 may be comprised of a variety of materials, such as tungsten, potentially also incorporating a contact silicide, such as nickel silicide (not shown in FIG. 2Q). The contact 254 may be formed by forming a patterned mask layer (not shown) above the layer of insulating material 252 and thereafter performing one or more etching processes to define an opening that extends through the layers of insulating materials 252, 224 and 222R and exposes the substrate 210 (or metal silicide regions) at the bottom of the opening. The precision needed for the lithographic patterning is relaxed by the etch guidance that gives rise to the contact self-alignment. Thereafter, the conductive material for the self-aligned contact 254 may be deposited into the opening in the layers of insulating materials 252, 224 and 222R with excess deposition material being removed by performing a CMP process step in a conventional manner.

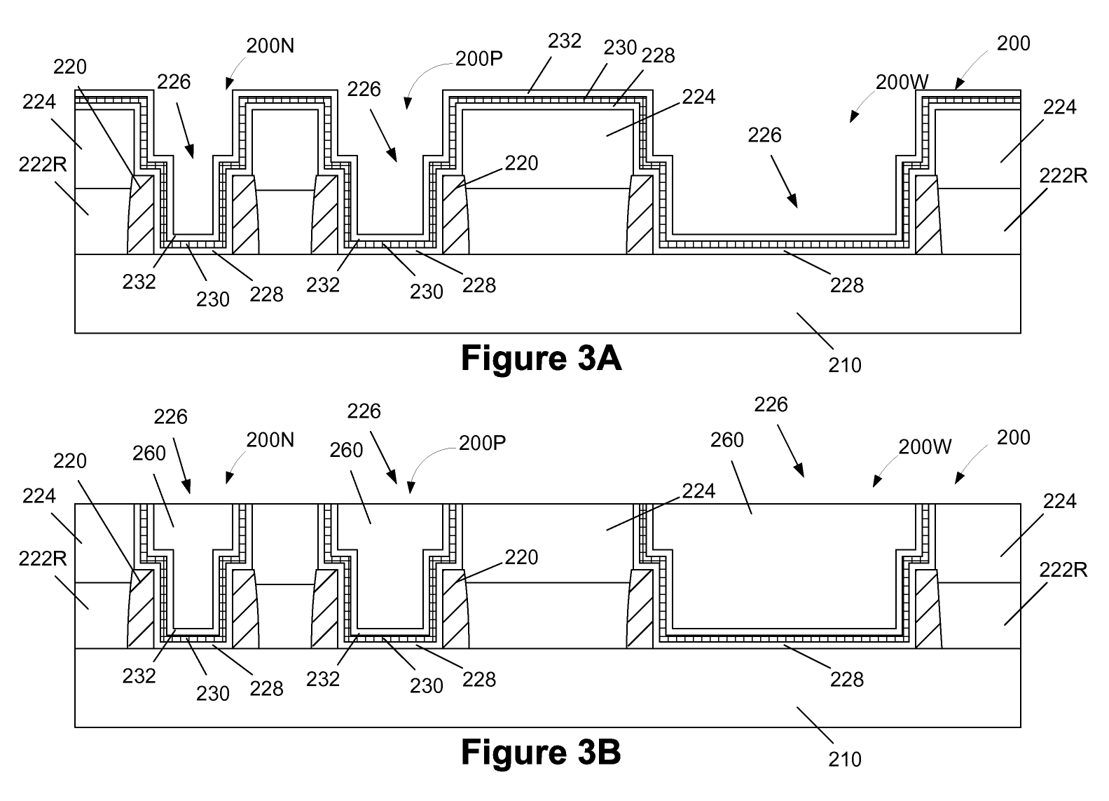

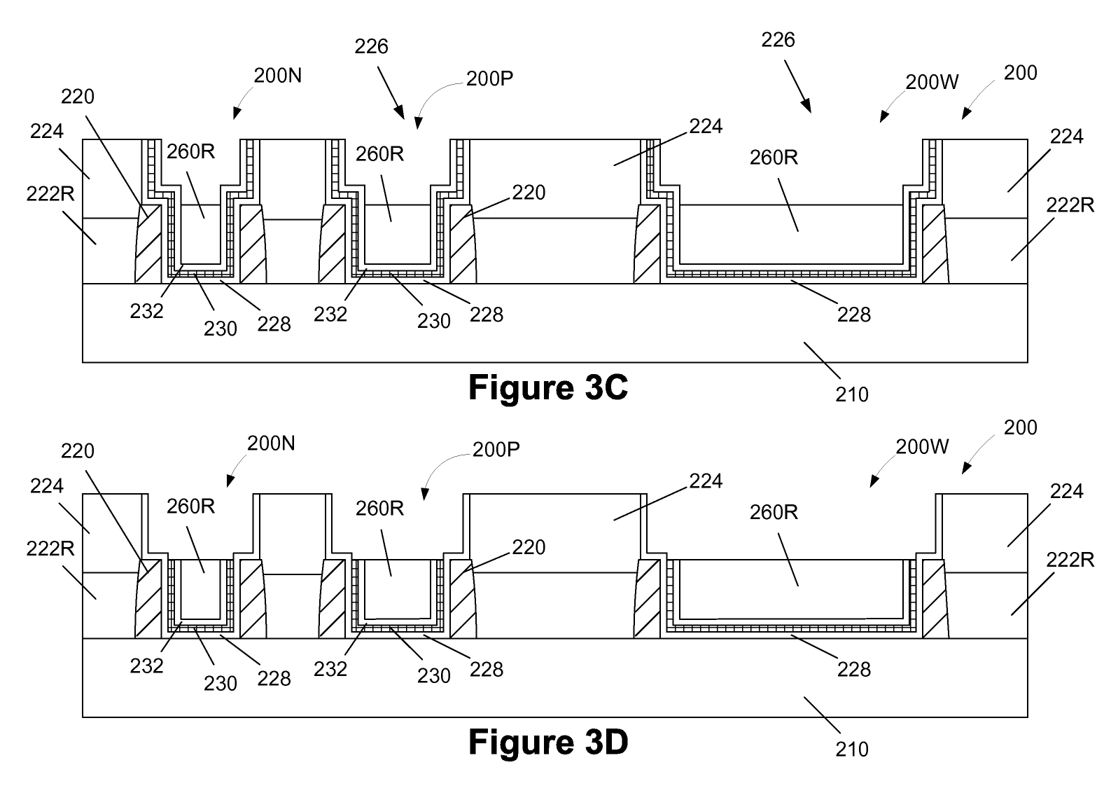

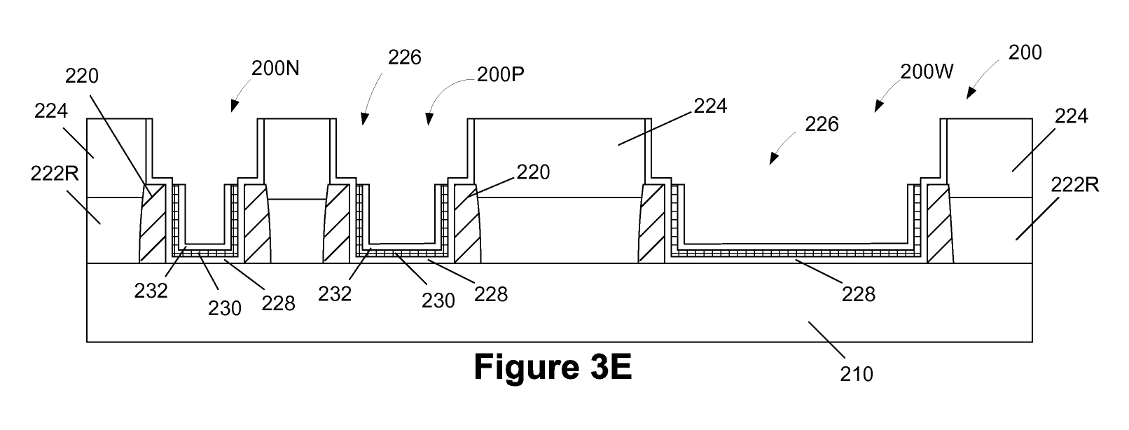

FIG. 3A-3E depict another illustrative method disclosed herein for forming replacement gate structures for FinFET or planar FET devices. FIG. 3A depicts the device 200 at the point of fabrication that corresponds to that depicted in FIG. 2I, wherein the high-k gate insulation layer 228, the first work function adjusting layer 230 and the second work function adjusting layer 232 have been formed in the gate cavities 226 for the devices 200N, 200P and 200W. Next, as shown in FIG. 3B, in this illustrative embodiment, a sacrificial material 260 is formed in the gate cavities 226. The sacrificial material 260 may be comprised of, for example, amorphous silicon, amorphous germanium, an organic photoresist layer, etc. The sacrificial material 260 may be formed by initially depositing a layer of the sacrificial material so as to over-fill the gate cavities 226 and thereafter performing a CMP process to remove excess portions of the layer of sacrificial material positioned outside of the gate cavities 226.

Next, as shown in FIG. 3C, in one illustrative embodiment, an etching process is performed to reduce the original thickness of the sacrificial material 260 and thereby define a reduced thickness sacrificial material 260R. In this illustrative example, a separate masking of the 200W device has intentionally not been performed. In another illustrative embodiment, where the sacrificial material 260 is comprised of a material that may be oxidized, a low-temperature oxidation process at a temperature of less than about 250° C. may be performed on the sacrificial material 260 to oxidize a portion of the sacrificial material 260 to a desired and controlled depth. Thereafter, the oxidized portion (not shown) of the sacrificial material 260 may be removed by performing an etching process to thereby result in the reduced thickness sacrificial material 260R. Note that, in this illustrative example, the material used for the insulation layer 224 should be comprised of a material that will not readily oxidize in a low-temperature oxidation process, such as, for example, silicon nitride.

Then, as shown in FIG. 3D, an etching process is performed to remove the exposed portions of the first work function adjusting layer 230 and the second work function adjusting layer 232 from within the cavities 226 of the NFET device 200N, the PFET device 200P and the wide device 200W. Next, as shown in FIG. 3E, an etching process is performed to remove the remainder of the sacrificial material 260R from the gate cavities 226. At this point in the process flow, each of the gate cavities 226 is comprised of the high-k layer of insulating material 228, the first work function adjusting layer 230 and the second work function adjusting layer 232 and, furthermore, the upward extent of those layers has now been appropriately limited. If desired, similar to the situation depicted in FIG. 2M, a masking layer (not shown) may be formed over one or more of the devices, e.g., over the PFET device 200P, and an etching process may be performed to remove the second work function adjusting layer 232 from within the cavities 226 of the NFET device 200N or the PFET device 200P or the wide device 200W, in a selective fashion if desired. The remaining steps to be performed are as described previously for the embodiment depicted in FIGS. 2A-2Q.

With reference to FIG. 2Q, another unique aspect of the subject matter disclosed herein will now be described. By removing the metal liner layers 230 and 232 first, portions of the reduced thickness conductive structure 244R extend above and touch the layer 230 (for NFET 250N) and the layers 230/232 (for the PFET 250P) and the reduced thickness conductive structure 244R also touch the high-k layer of insulating material 228 for both the NFET and PFET devices. In some application, it may be the PFET device that has the single metal layer (230) while the NFET device has a dual metal layer (230/232) configuration. In general, both the NFET device 200N and the PFET device 200P have a gate electrode structure 224R with a “T” shaped configuration, i.e., the width 275T at the top of the gate electrode 224 is greater that the width 275B at the bottom of the gate electrode 224R for both the NFET device 200N and the PFET device 200P. The transistor with the greater width at the top may be either an NFET or a PFET devices, or such devices may have approximately the same width at the top.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is, therefore, evident that the particular embodiments disclosed above may be altered or modified and all such variations are considered within the scope and spirit of the invention. Accordingly, the protection sought herein is as set forth in the claims below.

What is claimed:

1. A method of forming a transistor, comprising:
forming a sacrificial gate structure above a semiconducting substrate;
removing said sacrificial gate structure to thereby define a gate cavity;
forming a layer of insulating material in said gate cavity;
forming a layer of metal within said gate cavity above said layer of insulating material;
forming a sacrificial material in said gate cavity so as to cover a portion of said layer of metal and thereby define an exposed portion of said layer of metal;
performing an etching process on said exposed portion of said layer of metal to thereby remove said exposed portion of said layer of metal from within said gate cavity;
after performing said etching process, removing said sacrificial material; and
forming a conductive material above the previously covered portion of said layer of metal.

2. The method of claim 1, wherein said transistor is one of a FinFET device or a FET device.

3. The method of claim 1, wherein forming said sacrificial material comprises performing a bottom-up gap fill process to directly deposit said sacrificial material in said gate cavity to its final thickness.

4. The method of claim 1, wherein forming said sacrificial material comprises:
performing a deposition process to form a deposited layer of said sacrificial material that overfills said gate cavity;
performing a chemical mechanical polishing process on said deposited layer of sacrificial material; and
after performing said chemical mechanical polishing process, performing an etching process on said layer of sacrificial material to reduce its thickness.

5. The method of claim 1, wherein said layer of metal is a work function adjusting layer of metal for an N-type FET.

6. The method of claim 1, wherein said layer of metal is a work function adjusting layer of metal for a P-type FET.

7. The method of claim 1, wherein forming said sacrificial material comprises:
performing a deposition process to form a deposited layer of said sacrificial material that overfills said gate cavity;
performing a chemical mechanical polishing process on said deposited layer of sacrificial material;
after performing said chemical mechanical polishing process, performing an oxidation process on said layer of sacrificial material to oxidize an upper portions of said layer of sacrificial material while leaving a lower portion of said layer of sacrificial material in a non-oxidized state; and
performing an etching process to remove said oxidized upper portion of said layer of sacrificial material while leaving said lower portion of said layer of sacrificial material in place.

8. The method of claim 1, further comprising:
performing at least one etching process to partially recess said conductive material; and
forming an insulating material above said recessed conductive material within said gate cavity.

9. A method of forming a transistor, comprising:
forming a sacrificial gate structure above a semiconducting substrate;
removing said sacrificial gate structure to thereby define a gate cavity;
forming a layer of insulating material in said gate cavity;
forming a first layer of metal within said gate cavity above said layer of insulating material;
forming a second layer of metal within said gate cavity above said first layer of metal;
forming a sacrificial material in said gate cavity so as to cover a portion of said second layer of metal and thereby define an exposed portion of said first layer of metal and said second layer of metal;
performing at least one etching process on said exposed portions of said second layer of metal and said first layer of metal to thereby remove said exposed portions of said second layer of metal and said first layer of metal from within said gate cavity;
after performing said at least one etching process, removing said sacrificial material; and
forming a conductive gate electrode material above said previously covered portions of said first and second layers of metal.

10. The method of claim 9, wherein forming said sacrificial material comprises performing a bottom-up gap fill process to directly deposit said sacrificial material in said gate cavity to its final thickness.

11. The method of claim 9, wherein forming said sacrificial material comprises:
performing a deposition process to form a deposited layer of said sacrificial material that overfills said gate cavity;
performing a chemical mechanical polishing process on said deposited layer of sacrificial material; and
after performing said chemical mechanical polishing process, performing an etching process on said layer of sacrificial material to reduce its thickness.

12. The method of claim 9, wherein said first layer of metal is a work function adjusting layer of metal for an N-type FET and said second layer of metal is a work function adjusting layer of metal for a P-type FET.

13. The method of claim 9, wherein said first layer of metal is a work function adjusting layer of metal for a P-type FET and said second layer of metal is a work function adjusting layer of metal for an N-type FET.

14. The method of claim 9, further comprising:
performing at least one etching process to partially recess said conductive gate electrode material; and
forming an insulating material above said recessed conductive gate electrode material within said gate cavity.

15. The method of claim 9, wherein forming said sacrificial material comprises:
performing a deposition process to form a deposited layer of said sacrificial material that overfills said gate cavity;
performing a chemical mechanical polishing process on said deposited layer of sacrificial material;
after performing said chemical mechanical polishing process, performing an oxidation process on said layer of sacrificial material to oxidize an upper portion of said layer of sacrificial material while leaving a lower portion of said layer of sacrificial material in a non-oxidized state; and
performing an etching process to remove said oxidized upper portion of said layer of sacrificial material while leaving said lower portion of said layer of sacrificial material in place.

16. A method of forming first and second transistors, comprising:
forming a sacrificial gate structure above a semiconducting substrate for each of said first and second transistor;
removing said sacrificial gate structures to thereby define a first gate cavity and a second gate cavity for each of said first and second transistors, respectively;
forming a layer of insulating material in each of said first and second gate cavities;
forming a first layer of metal within in each of said first and second gate cavities above said layer of insulating material;
forming a second layer of metal within each of said first and second gate cavities above said first layer of metal;
forming a sacrificial material within each of said first and second gate cavities so as to cover a portion of said second layer of metal and thereby define an exposed portion of said first layer of metal and said second layer of metal;
performing at least one etching process on said exposed portions of said second layer of metal and said first layer of metal to thereby remove said exposed portions of said second layer of metal and said first layer of metal from within each of said first and second gate cavities; and
after performing said at least one etching process, removing said sacrificial material.

17. The method of claim 16, further comprising forming a conductive gate electrode material above said remaining portions of said first and second layers of metal in one of said first and second cavities.

18. The method of claim 17, further comprising:
performing at least one etching process to partially recess said conductive gate electrode material; and
forming an insulating material above said recessed conductive gate electrode material within at least one of said first and second gate cavities.

19. The method of claim 16, wherein said first and second transistors are FinFET devices.

20. The method of claim 16, wherein said first and second transistors are FET devices.

21. The method of claim 16, wherein forming said sacrificial material comprises performing a bottom-up gap fill process to directly deposit said sacrificial material in said gate cavity to its final thickness.

22. The method of claim 16, wherein forming said sacrificial material comprises:
performing a deposition process to form a deposited layer of said sacrificial material that overfills said first and second gate cavities;
performing a chemical mechanical polishing process on said deposited layer of sacrificial material; and
after performing said chemical mechanical polishing process, performing an etching process on said layer of sacrificial material to reduce its thickness.

23. The method of claim 16, wherein said first layer of metal is a work function adjusting layer of metal for an N-type FET and said second layer of metal is a work function adjusting layer of metal for a P-type FET.

24. The method of claim 16, wherein said first layer of metal is a work function adjusting layer of metal for a P-type FET and said second layer of metal is a work function adjusting layer of metal for an N-type FET.

25. The method of claim 16, further comprising:
forming a masking layer that masks at least said first cavity and exposes said second cavity for further processing; and
performing an etching process to remove said remaining portion of said second layer of metal from within said first cavity while leaving said remaining portion of said first layer of metal within said first cavity.

26. The method of claim 16, wherein forming said sacrificial material comprises:
performing a deposition process to form a deposited layer of said sacrificial material that overfills said gate cavity;
performing a chemical mechanical polishing process on said deposited layer of sacrificial material;
after performing said chemical mechanical polishing process, performing an oxidation process on said layer of sacrificial material to oxidize an upper portion of said layer of sacrificial material while leaving a lower portion of said layer of sacrificial material in a non-oxidized state; and
performing an etching process to remove said oxidized upper portion of said layer of sacrificial material while leaving said lower portion of said layer of sacrificial material in place.

27. A device, comprising:
a first transistor and a second transistor formed in and above a semiconducting substrate, each of said first and second transistors comprising a gate insulation layer, a first work function adjusting metal layer positioned above the gate insulation layer and a gate electrode positioned above the first work function adjusting metal layer, wherein said gate electrode for each of said first and second transistors has an upper portion with a width at its top that is greater than a width of a lower portion of said gate electrode at its bottom; and
a second work function adjusting layer positioned only in said second transistor, said second work function adjusting layer being positioned between said first work function adjusting layer and said gate electrode in said second transistor only, wherein said upper portion of said gate electrode of said first transistor is positioned above and contacts an upper surface of said first work function adjusting layer and also contacts said gate insulation layer, while said upper portion of said gate electrode of said second transistor is positioned above and contacts an upper surface of each of said first and second work function adjusting layers and also contacts said gate insulation layer.

28. The device of claim 27, wherein said first transistor has a smaller gate length than said second transistor.

29. The device of claim 27, wherein said first transistor has a larger gate length than said second transistor.

30. The device of claim 27, wherein said first transistor is an NFET device and said second transistor is a PFET device.

31. The device of claim 27, wherein said first transistor is an PFET device and said second transistor is a NFET device.

32. The device of claim 27, wherein said top width of said gate electrode for said first transistor is less than said top width of said gate electrode for said second transistor.

33. The device of claim 27, wherein said top width of said gate electrode for said second transistor is less than said top width of said gate electrode for said first transistor.

34. The device of claim 27, wherein said contact between said gate insulation layer and said upper portions of said gate electrodes of said first and second transistors is along a substantially vertically oriented edge of said upper portion of said gate electrodes of each of said first and second transistors.
